(19) United States
(12) Patent Application Publication
(10) Pub. No.: US 2026/0367318 A1
(43) Pub. Date: Nov. 19, 2026

(54) OPTICAL SEMICONDUCTOR INTEGRATED DEVICE

(71) Applicant: Mitsubishi Electric Corporation, Tokyo (JP)

(72) Inventors: Kenichi ABE, Chiyoda-ku, Tokyo (JP); Satoshi NISHIKAWA, Chiyoda-ku, Tokyo (JP)

(73) Assignee: Mitsubishi Electric Corporation, Tokyo (JP)

(21) Appl. No.: 19/121,153

(22) PCT Filed: Dec. 13, 2022
(86) PCT No.: PCT/JP2022/045808

§ 371 Date: Apr. 15, 2025

(51) Int. Cl. G02B 6/122; G02B 6/12

(52) U.S. Cl. CPC G02B 6/1225; G02B 2006/12078; G02B 2006/12121; G02B 2006/12142

(57) ABSTRACT

An optical semiconductor integrated device includes an optical modulation section, and a semiconductor waveguide element section connected to the optical modulation section. The optical modulation section includes an active layer, an upper cladding layer, and a first semiconductor region having the same conductivity type as that of the upper cladding layer. The first semiconductor region is disposed on a part between the active layer and the upper cladding layer. A first impact ionization coefficient of the first semiconductor region is smaller than an impact ionization coefficient of the upper cladding layer.

### TECHNICAL FIELD

The present disclosure relates to an optical semiconductor integrated device.

### BACKGROUND ART

Japanese Patent Laying-Open No. 2008-305981 (PTL 1) discloses a semiconductor laser element including a DFB laser and an optical modulator. In order to prevent end surface destruction due to electrostatic discharge (ESD), in the semiconductor laser element in PTL 1, the optical modulator has a first portion including an output-side end surface and a second portion, and the thickness of an insulating region of an active layer in the first portion is thicker than the thickness of an insulating region of an active layer in the second portion.

### CITATION LIST

### Patent Literature

PTL 1: Japanese Patent Laying-Open No. 2008-305981

### SUMMARY OF INVENTION

### Technical Problem

However, when the thickness of the insulating region of the active layer in the first portion is increased, the intensity of an electric field applied to the optical modulator is decreased, and the extinction ratio of the optical modulator is reduced. The present disclosure has been made in view of the aforementioned problem, and an object thereof is to provide an optical semiconductor integrated device having an improved resistance to ESD without reducing the extinction ratio of an optical modulation section.

### Solution to Problem

An optical semiconductor integrated device according to the present disclosure includes an optical modulation section, and a semiconductor waveguide element section connected to the optical modulation section. The optical modulation section includes an active layer, an upper cladding layer, and a first semiconductor region having a same conductivity type as that of the upper cladding layer. The first semiconductor region is disposed on a part between the active layer and the upper cladding layer. A first impact ionization coefficient of the first semiconductor region is smaller than an impact ionization coefficient of the upper cladding layer.

### Advantageous Effects of Invention

Accordingly, in the first semiconductor region, occurrence of impact ionization in a chained manner during optical modulation is suppressed. Even when an instantaneous high voltage due to static electricity is applied to the optical modulation section, it is possible to prevent a large current due to avalanche breakdown from flowing through the optical modulation section, without increasing the thickness of the active layer. According to the optical semiconductor integrated device according to the present disclosure, the resistance to electrostatic destruction (ESD) can be improved without reducing the extinction ratio of the optical modulation section.

### BRIEF DESCRIPTION OF DRAWINGS

FIG. 1 is a schematic plan view of an optical semiconductor integrated device according to an embodiment.

FIG. 2 is a schematic cross sectional view of the optical semiconductor integrated device according to the embodiment, taken along a cross sectional line II-II shown in FIG. 1.

FIG. 3 is a schematic cross sectional view of the optical semiconductor integrated device according to the embodiment, taken along a cross sectional line III-III shown in FIG. 1.

FIG. 4 is a schematic cross sectional view of the optical semiconductor integrated device according to the embodiment, taken along a cross sectional line IV-IV shown in FIG. 1.

FIG. 5 is a schematic cross sectional view of the optical semiconductor integrated device according to the embodiment, taken along a cross sectional line V-V shown in FIG. 1.

FIG. 6 is a schematic cross sectional view of the optical semiconductor integrated device according to the embodiment, taken along a cross sectional line VI-VI shown in FIG. 1.

FIG. 7 is a schematic cross sectional view of the optical semiconductor integrated device according to the embodiment, taken along a cross sectional line VII-VII shown in FIG. 1.

FIG. 8 is a schematic cross sectional view of the optical semiconductor integrated device according to a first variation of the embodiment.

FIG. 9 is a schematic cross sectional view of the optical semiconductor integrated device according to a second variation of the embodiment.

### DESCRIPTION OF EMBODIMENTS

Hereinafter, an embodiment of the present disclosure will be described. It should be noted that identical components will be designated by the same reference numerals, and the description thereof will not be repeated.

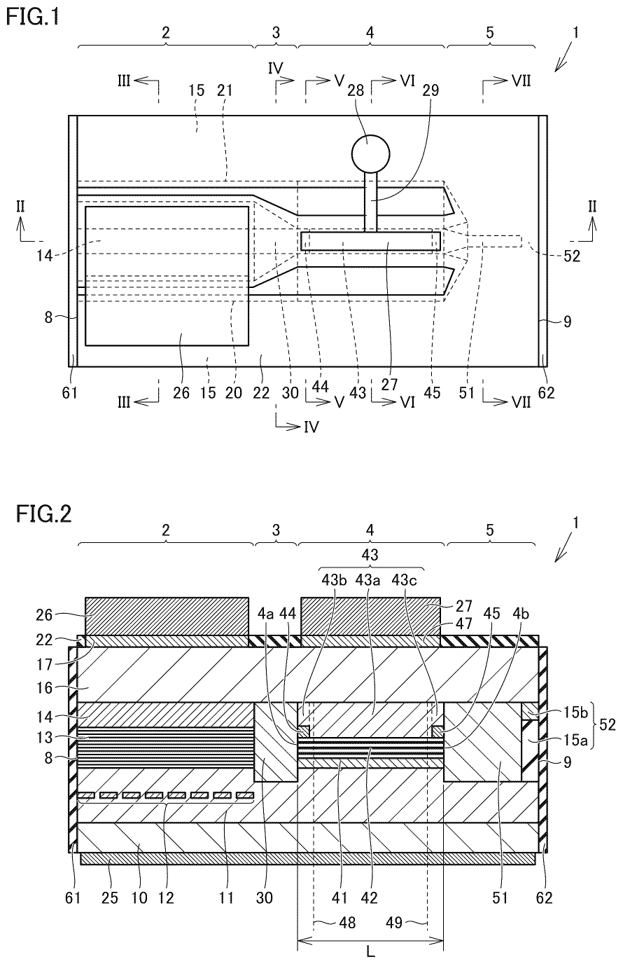

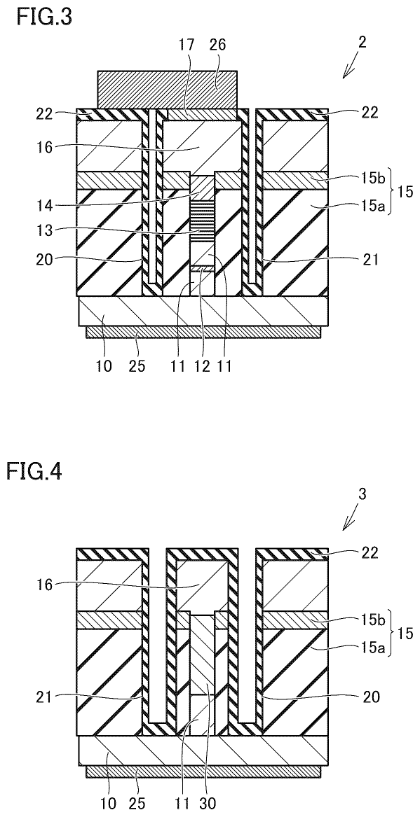

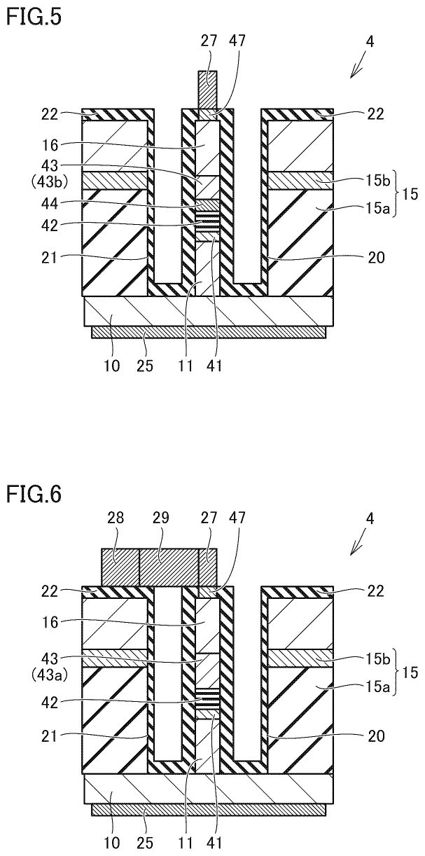

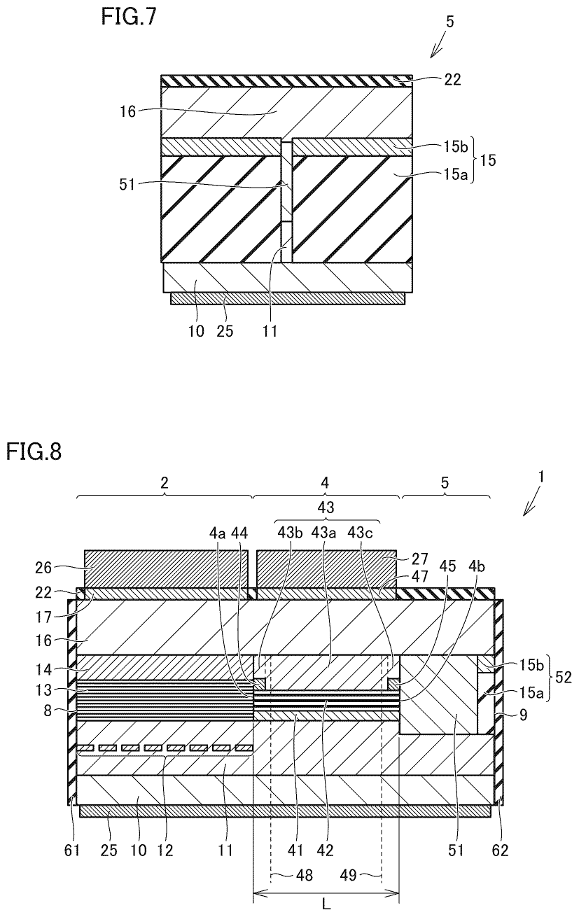

Referring to FIGS. 1 to 7, an optical semiconductor integrated device 1 according to the embodiment will be described. Optical semiconductor integrated device 1 includes a laser section 2, a passive waveguide section 3, an optical modulation section 4, a spot size conversion section 5, a high reflection film 61, and an antireflection film 62. Laser section 2, passive waveguide section 3, optical modulation section 4, and spot size conversion section 5 are disposed along a direction of an optical axis of optical semiconductor integrated device 1.

Specifically, optical semiconductor integrated device 1 includes a semiconductor substrate 10. Semiconductor substrate 10 is an n-InP substrate, for example. Laser section 2, passive waveguide section 3, optical modulation section 4, and spot size conversion section 5 share semiconductor substrate 10. Optical semiconductor integrated device 1 includes end surfaces 8 and 9. End surface 9 is an output end surface of optical semiconductor integrated device 1.

Referring to FIGS. 1 to 3, laser section 2 includes semiconductor substrate 10, a lower cladding layer 11, a diffraction grating 12, a first active layer 13, an upper cladding layer 14, a current blocking layer 15, an upper cladding layer 16, a contact layer 17, an insulating protective film 22, a first electrode 25, and a second electrode 26. Laser section 2 includes end surface 8.

Lower cladding layer 11 is disposed on an upper surface of semiconductor substrate 10. Lower cladding layer 11 is an n-type semiconductor layer such as an n-InP layer, for example. Diffraction grating 12 is embedded in lower cladding layer 11. Diffraction grating 12 functions as a distributed Bragg reflector (DBR), for example.

First active layer 13 is disposed on lower cladding layer 11. First active layer 13 is a multiple quantum well (MQW) layer, for example. First active layer 13 is an intrinsic semiconductor layer (i layer) not intentionally doped with an n-type dopant and a p-type dopant, for example. First active layer 13 is disposed between lower cladding layer 11 and upper cladding layer 14, and has a refractive index higher than those of lower cladding layer 11 and upper cladding layer 14.

Upper cladding layer 14 is disposed on first active layer 13. Upper cladding layer 14 is a p-type semiconductor layer such as a p-InP layer, for example.

Current blocking layer 15 is disposed on the upper surface of semiconductor substrate 10. Current blocking layer 15, both side surfaces of a stacked body of lower cladding layer 11, first active layer 13, and upper cladding layer 14 are embedded by current blocking layer 15. Laser section 2 has an embedded structure. Current blocking layer 15 includes a semi-insulating semiconductor layer 15a and an n-type semiconductor layer 15b, for example. Semi-insulating semiconductor layer 15a is disposed on the upper surface of semiconductor substrate 10. Semi-insulating semiconductor layer 15a is an Fe-doped InP layer, for example. n-type semiconductor layer 15b is disposed on semi-insulating semiconductor layer 15a. n-type semiconductor layer 15b is an n-InP layer, for example.

Upper cladding layer 16 is disposed on upper cladding layer 14 and the current blocking layer (n-type semiconductor layer 15b). Upper cladding layer 16 and n-type semiconductor layer 15b form a pn junction. Upper cladding layer 16 may be formed of the same semiconductor material as that for upper cladding layer 14. Upper cladding layer 16 is a p-type semiconductor layer such as a p-InP layer, for example.

Grooves 20 and 21 are provided in current blocking layer 15 and upper cladding layer 16. Grooves 20 and 21 reach the upper surface of semiconductor substrate 10. Grooves 20 and 21 separate a central portion of optical semiconductor integrated device 1 located between grooves 20 and 21 from a peripheral portion of optical semiconductor integrated device 1 located outside grooves 20 and 21.

Insulating protective film 22 is disposed on surfaces of grooves 20 and 21 and on upper cladding layer 16. Insulating protective film 22 is a SiO₂ film, for example. Insulating protective film 22 is provided with openings.

Contact layer 17 is disposed on upper cladding layer 16 exposed from an opening of insulating protective film 22. Contact layer 17 has the same conductivity type as that of upper cladding layers 14 and 16, and is doped with more dopant than those for upper cladding layers 14 and 16. Contact layer 17 is a p⁺-InGaAs layer, for example.

First electrode 25 is formed on a lower surface of semiconductor substrate 10. Second electrode 26 is disposed on contact layer 17. First electrode 25 and second electrode 26 are gold (Au) electrodes, for example.

An upper surface of first active layer 13 is in contact with upper cladding layer 14, and a lower surface of first active layer 13 is in contact with lower cladding layer 11. Upper cladding layer 14, first active layer 13, and lower cladding layer 11 form a pin structure. A voltage higher than that of first electrode 25 is applied to second electrode 26 to apply a forward bias voltage to the pin structure of laser section 2. A current is injected into first active layer 13, and laser section 2 emits laser light.

Semi-insulating semiconductor layer 15a allows less current to flow therethrough than upper cladding layer 14, first active layer 13, and lower cladding layer 11. Further, when a forward bias voltage is applied to the pin structure using first electrode 25 and second electrode 26, a reverse bias voltage is applied to a pn junction formed by upper cladding layer 14 and n-type semiconductor layer 15b, and thus a current is less likely to flow through the pn junction. Accordingly, current blocking layer 15 blocks a current flowing between first electrode 25 and second electrode 26, and concentrates the current on first active layer 13.

Referring to FIGS. 1, 2, and 4, passive waveguide section 3 includes semiconductor substrate 10, lower cladding layer 11, a passive waveguide 30, current blocking layer 15, upper cladding layer 16, and insulating protective film 22. Passive waveguide section 3 may include first electrode 25.

Passive waveguide 30 is disposed on lower cladding layer 11. Upper cladding layer 16 is disposed on passive waveguide 30. Passive waveguide 30 is disposed between lower cladding layer 11 and upper cladding layer 16, and has a refractive index higher than those of lower cladding layer 11 and upper cladding layer 16.

Passive waveguide 30 is formed of a semiconductor material (for example, InGaAsP) having a band gap larger than the energy of the laser light emitted from laser section 2. Passive waveguide 30 is an intrinsic semiconductor layer, for example. Both side surfaces of a stacked body of lower cladding layer 11 and passive waveguide 30 are embedded by current blocking layer 15. Passive waveguide 30 is connected to first active layer 13 of laser section 2 and a second active layer 42 of optical modulation section 4, and optically couples first active layer 13 and second active layer 42.

Passive waveguide 30 guides the laser light emitted from laser section 2 to second active layer 42 of optical modulation section 4.

In passive waveguide 30, the width of each of grooves 20 and 21 gradually increases and the width of the current blocking layer disposed between grooves 20 and 21 gradually decreases from laser section 2 toward optical modulation section 4. The width of the current blocking layer disposed between grooves 20 and 21 becomes zero at a connection portion between passive waveguide section 3 and optical modulation section 4.

Referring to FIGS. 1, 2, 5, and 6, optical modulation section 4 includes an end surface 4a, and an end surface 4b opposite to end surface 4a. End surface 4a and end surface 4b are both end surfaces of optical modulation section 4 in the direction of the optical axis of optical semiconductor integrated device 1. In the present embodiment, optical modulation section 4 is disposed between passive waveguide section 3 and spot size conversion section 5, and is connected to passive waveguide section 3 and spot size conversion section 5. End surface 4a faces passive waveguide section 3, and is an interface between passive waveguide section 3 and optical modulation section 4. End surface 4b faces spot size conversion section 5, and is an interface between optical modulation section 4 and spot size conversion section 5. A modulation section length L (see FIG. 2) is a distance between end surface 4a and end surface 4b in second active layer 42.

Optical modulation section 4 includes semiconductor substrate 10, lower cladding layer 11, a lower cladding layer 41, second active layer 42, an upper cladding layer 43, a semiconductor region 44, a semiconductor region 45, current blocking layer 15, upper cladding layer 16, a contact layer 47, insulating protective film 22, first electrode 25, a third electrode 27, a pad 28, and a bridge wire 29.

Lower cladding layer 41 is disposed on lower cladding layer 11. Lower cladding layer 41 may be formed of the same semiconductor material as that for lower cladding layer 11. Lower cladding layer 41 is an n-type semiconductor layer such as an n-InP layer, for example.

Second active layer 42 is disposed on lower cladding layer 41. Second active layer 42 is a multiple quantum well (MQW) layer, for example. Second active layer 42 is an intrinsic semiconductor layer (i layer) not intentionally doped with an n-type dopant and a p-type dopant, for example. Second active layer 42 is disposed between lower cladding layer 41 and upper cladding layer 43, and has a refractive index higher than those of lower cladding layer 41 and upper cladding layer 43.

Upper cladding layer 43 is disposed on second active layer 42. Upper cladding layer 43 may be formed of the same semiconductor material as that for upper cladding layer 16. Upper cladding layer 43 is a p-type semiconductor layer such as a p-InP layer.

Upper cladding layer 43 includes a first portion 43a, a second portion 43b, and a third portion 43c. Second portion 43b is proximal to end surface 8 relative to first portion 43a. Third portion 43c is proximal to end surface 9 relative to first portion 43a. A lower surface of first portion 43a is in contact with second active layer 42. A lower surface of second portion 43b is recessed from first portion 43a, and second portion 43b is away from second active layer 42. A lower surface of third portion 43c is recessed from first portion 43a, and third portion 43c is away from second active layer 42. Second portion 43b is in contact with semiconductor region 44. Third portion 43c is in contact with semiconductor region 45. The thickness of second portion 43b is smaller than the thickness of first portion 43a. The sum of the thickness of second portion 43b and the thickness of semiconductor region 44 is equal to the thickness of first portion 43a. The thickness of third portion 43c is smaller than the thickness of first portion 43a. The sum of the thickness of third portion 43c and the thickness of semiconductor region 45 is equal to the thickness of first portion 43a.

Both side surfaces of a stacked body of upper cladding layer 16, upper cladding layer 43, second active layer 42, lower cladding layer 41, and lower cladding layer 11 define the surfaces of grooves 20 and 21, and are covered with insulating protective film 22. Optical modulation section 4 has a high mesa structure.

Contact layer 47 is disposed on upper cladding layer 16 exposed from an opening of insulating protective film 22. Contact layer 47 has the same conductivity type as that of upper cladding layers 16 and 43, and is doped with more dopant than those for upper cladding layers 16 and 43. Contact layer 47 is a p⁺-InGaAs layer, for example.

Third electrode 27 is disposed on contact layer 47. Third electrode 27 is a gold (Au) electrode, for example. A conductive wire (not shown) is bonded to pad 28. Bridge wire 29 is connected to third electrode 27 and pad 28 across groove 21. A voltage from an external power source (not shown) is applied to third electrode 27 through the conductive wire, pad 28, and bridge wire 29.

Semiconductor region 44 has the same conductivity type as that of upper cladding 16 and 43 layers. Semiconductor region 44 is disposed on a part between second active layer 42 and upper cladding layer 43. Semiconductor region 44 is in contact with second active layer 42, upper cladding layer 43, and passive waveguide section 3 (specifically, passive waveguide 30). Semiconductor region 44 and upper cladding layer 43 are in contact with an upper surface of second active layer 42. A lower surface of semiconductor region 44 and the lower surface of first portion 43a of upper cladding layer 43 are flush with each other. Semiconductor region 44 is disposed on end surface 4a, and constitutes a part of end surface 4a. Semiconductor region 44 is disposed between end surface 4a and a first imaginary surface 48 that is away from end surface 4a by one tenth of modulation section length L.

A first impact ionization coefficient of semiconductor region 44 is smaller than an impact ionization coefficient of upper cladding layer 43. For example, when upper cladding layer 43 is formed of p-InP, semiconductor region 44 is formed of InGaAsP. Semiconductor region 44 may be lattice-matched to upper cladding layers 16 and 43. In the present specification, lattice matching of a semiconductor region to a cladding layer means that a difference between a lattice constant of a semiconductor material constituting the semiconductor region and a lattice constant of a semiconductor material constituting the cladding layer is within ±0.1% of the lattice constant of the semiconductor material constituting the cladding layer. Semiconductor region 44 is formed of In_{0.82}Ga_{0.18}As_{0.4}P_{0.6}, for example.

Semiconductor region 45 has the same conductivity type as that of upper cladding layers 16 and 43. Semiconductor region 45 is disposed on a part between second active layer 42 and upper cladding layer 43, and is away from semiconductor region 44. Semiconductor region 45 is in contact with second active layer 42, upper cladding layer 43, and spot size conversion section 5 (specifically, a spot size conversion waveguide 51). Semiconductor region 45 and upper cladding layer 43 are in contact with the upper surface of second active layer 42. A lower surface of semiconductor region 45 and the lower surface of first portion 43a of upper cladding layer 43 are flush with each other. Semiconductor region 45 is disposed on end surface 4b, and constitutes a part of end surface 4b. Semiconductor region 45 is disposed between end surface 4b and a second imaginary surface 49 that is away from end surface 4b by one tenth of modulation section length L.

A second impact ionization coefficient of semiconductor region 45 is smaller than the impact ionization coefficient of upper cladding layer 43. Semiconductor region 45 may be formed of the same material as that for semiconductor region 44.

For example, when upper cladding layer 43 is formed of p-InP, semiconductor region 45 is formed of InGaAsP. Semiconductor region 45 may be lattice-matched to upper cladding layers 16 and 43. Semiconductor region 45 is formed of In_{0.82}Ga_{0.18}As_{0.4}P_{0.6}, for example.

The upper surface of second active layer 42 is in contact with upper cladding layer 43, semiconductor region 44, and semiconductor region 45, and a lower surface of second active layer 42 is in contact with lower cladding layer 41. Upper cladding layer 43, semiconductor region 44, semiconductor region 45, second active layer 42, and lower cladding layer 41 form a pin structure. When a reverse bias voltage is not applied to the pin structure of optical modulation section 4, second active layer 42 allows the laser light emitted from laser section 2 to pass therethrough. When a reverse bias voltage is applied to the pin structure of optical modulation section 4 by applying a voltage lower than that of first electrode 25 to third electrode 27, an absorption edge wavelength of second active layer 42 moves to a longer wavelength side, and second active layer 42 absorbs the laser light emitted from laser section 2. In this manner, optical modulation section 4 modulates the intensity of the laser light.

Referring to FIGS. 1, 2, and 7, spot size conversion section 5 increases the diameter of the laser light emitted from laser section 2 in order to increase the coupling efficiency of the laser light to an optical element (not shown) such as an optical fiber. Spot size conversion section 5 includes semiconductor substrate 10, lower cladding layer 11, spot size conversion waveguide 51, current blocking layer 15, upper cladding layer 16, insulating protective film 22, and a window region 52. Spot size conversion section 5 includes end surface 9. Spot size conversion section 5 may include first electrode 25.

Spot size conversion waveguide 51 is disposed on lower cladding layer 11. Upper cladding layer 16 is disposed on spot size conversion waveguide 51. Spot size conversion waveguide 51 is disposed between lower cladding layer 11 and upper cladding layer 16, and has a refractive index higher than those of lower cladding layer 11 and upper cladding layer 16. Spot size conversion waveguide 51 is formed of a semiconductor material (for example, InGaAsP) having a band gap larger than the energy of the laser light emitted from laser section 2. Spot size conversion waveguide 51 may be formed of the same material as that for passive waveguide 30. Spot size conversion waveguide 51 is an intrinsic semiconductor layer, for example. Both side surfaces of a stacked body of lower cladding layer 11 and spot size conversion waveguide 51 are embedded by current blocking layer 15.

The width of spot size conversion waveguide 51 gradually decreases from optical modulation section 4 toward end surface 9. Accordingly, confinement of the laser light by spot size conversion waveguide 51 becomes weaker and the diameter of the laser light gradually increases from optical modulation section 4 toward end surface 9. Spot size conversion waveguide 51 is away from end surface 9.

Window region 52 is disposed on lower cladding layer 11. Upper cladding layer 16 is disposed on window region 52. Window region 52 is disposed between lower cladding layer 11 and upper cladding layer 16. Window region 52 is disposed between spot size conversion waveguide 51 and end surface 9. Window region 52 includes end surface 9. Window region 52 may have the same configuration as that of current blocking layer 15. For example, window region 52 includes semi-insulating semiconductor layer 15a and n-type semiconductor layer 15b. In window region 52, the diameter of the laser light further increases.

Referring to FIGS. 1 and 2, high reflection film 61 is formed on end surface 8. High reflection film 61 reflects the laser light generated in laser section 2 with a high reflectance (for example, a reflectance of 95% or more). High reflection film 61 is a multilayer film formed of a SiO₂ film, a Si film, an Al₂O₃ film, or the like, for example.

Referring to FIGS. 1 and 2, antireflection film 62 is formed on end surface 9. Antireflection film 62 prevents the laser light generated in laser section 2 from being reflected at end surface 9, and outputs the laser light from end surface 9 with a high extraction efficiency. Antireflection film 62 is a multilayer film formed of a SiO₂ film, a Si film, an Al₂O₃ film, or the like, for example.

An example of a method for manufacturing optical semiconductor integrated device 1 according to the present embodiment will be described.

Lower cladding layer 11 is formed on the upper surface of semiconductor substrate 10. For example, lower cladding layer 11 is deposited on the upper surface of semiconductor substrate 10, using metal organic chemical vapor deposition (MOCVD) or the like. Diffraction grating 12 is formed only in a region of lower cladding layer 11 where laser section 2 is to be formed.

First active layer 13 and upper cladding layer 14 are formed on lower cladding layer 11. For example, first active layer 13 and upper cladding layer 14 are formed on the entire upper surface of lower cladding layer 11, using metal organic chemical vapor deposition (MOCVD) or the like. First active layer 13 and upper cladding layer 14 are patterned by photolithography and etching. First active layer 13 and upper cladding layer 14 are formed in the region where laser section 2 is to be formed.

The region where laser section 2 is to be formed is covered with a mask. Then, lower cladding layer 41, second active layer 42, and upper cladding layer 43 are formed on the entire upper surface of lower cladding layer 11 exposed from the mask, using metal organic chemical vapor deposition (MOCVD) or the like. Lower cladding layer 41, second active layer 42, and upper cladding layer 43 are patterned by photolithography and etching. Lower cladding layer 41, second active layer 42, and upper cladding layer 43 are formed in a region where optical modulation section 4 is to be formed.

In addition to the region where laser section 2 is to be formed, the region where optical modulation section 4 is to be formed is covered with a mask. Then, passive waveguide 30 and spot size conversion waveguide 51 are formed on the entire upper surface of lower cladding layer 11 exposed from the mask, using metal organic chemical vapor deposition (MOCVD) or the like. Passive waveguide 30 and spot size conversion waveguide 51 are patterned by photolithography and etching. Passive waveguide 30 is formed in a region where passive waveguide section 3 is to be formed, and spot size conversion waveguide 51 is formed in a region where spot size conversion section 5 is to be formed.

Current blocking layer 15 and window region 52 are formed on the upper surface of semiconductor substrate 10, using metal organic chemical vapor deposition (MOCVD) or the like. Both side surfaces of lower cladding layer 11, first active layer 13, upper cladding layer 14, passive waveguide 30, lower cladding layer 41, second active layer 42, upper cladding layer 43, and spot size conversion waveguide 51 are embedded by current blocking layer 15.

Upper cladding layer 16 is formed on upper cladding layer 14, passive waveguide 30, upper cladding layer 43, spot size conversion waveguide 51, and current blocking layer 15, using metal organic chemical vapor deposition (MOCVD) or the like. Contact layers 17 and 47 are formed on upper cladding layer 16, using metal organic chemical vapor deposition (MOCVD) or the like.

Current blocking layer 15 is etched to form grooves 20 and 21. The both side surfaces of lower cladding layer 41, second active layer 42, and upper cladding layer 43 are exposed from current blocking layer 15, and optical modulation section 4 has a high mesa structure. The both side surfaces of lower cladding layer 11, first active layer 13, and upper cladding layer 14 remain covered with current blocking layer 15, and laser section 2 has an embedded structure. The both side surfaces of passive waveguide 30 and spot size conversion waveguide 51 remain covered with current blocking layer 15.

Insulating protective film 22 is formed on the surfaces of grooves 20 and 21 and on upper cladding layer 16, using chemical vapor deposition (CVD) or the like. Insulating protective film 22 is provided with openings by etching. First electrode 25, second electrode 26, third electrode 27, pad 28, and bridge wire 29 are formed using vapor deposition, photolithography, etching, and the like. First electrode 25 is formed on the lower surface of semiconductor substrate 10. Second electrode 26 is formed on contact layer 17. Third electrode 27 is formed on contact layer 47. Pad 28 is formed on insulating protective film 22. Bridge wire 29 connects third electrode 27 and pad 28 across groove 21.

End surfaces 8 and 9 are formed by cleavage. High reflection film 61 is formed on end surface 8, using chemical vapor deposition (CVD) or the like. Antireflection film 62 is formed on end surface 9, using chemical vapor deposition (CVD) or the like. In this manner, optical semiconductor integrated device 1 is obtained.

An operation of optical semiconductor integrated device 1 according to the present embodiment will be described.

A voltage higher than that of first electrode 25 is applied to second electrode 26 to apply a forward bias voltage to the pin structure of laser section 2. A current is injected into first active layer 13, and laser section 2 emits laser light. End surface 8 and an end surface of laser section 2 facing passive waveguide section 3 each function as an optical resonator for the laser light. Since high reflection film 61 is formed on end surface 8, the intensity of the laser light can be increased. For example, diffraction grating 12 functions as a distributed Bragg reflector (DBR) for the laser light. Laser section 2 is a distributed feedback laser (DFB laser).

Passive waveguide 30 guides the laser light from laser section 2 to second active layer 42 of optical modulation section 4.

When a reverse bias voltage is not applied to the pin structure of optical modulation section 4, second active layer 42 allows the laser light emitted from laser section 2 to pass therethrough. When a reverse bias voltage is applied to the pin structure of optical modulation section 4 by applying a voltage lower than that of first electrode 25 to third electrode 27, the absorption edge wavelength of second active layer 42 moves to the longer wavelength side, and second active layer 42 absorbs the laser light emitted from laser section 2. In this manner, optical modulation section 4 modulates the intensity of the laser light.

The laser light modulated in optical modulation section 4 enters spot size conversion waveguide 51 of spot size conversion section 5. As the laser light travels through spot size conversion waveguide 51 and window region 52, the diameter of the laser light gradually increases. Further, antireflection film 62 is provided on end surface 9. Accordingly, the laser light can be coupled to an optical element (not shown) such as an optical fiber, disposed to face end surface 9, with a high coupling efficiency.

When the reverse bias voltage is applied to the pin structure of optical modulation section 4, a depletion layer is formed in the pin structure of optical modulation section 4, and therefore, generally, no current flows through the pin structure of optical modulation section 4. However, when an instantaneous high voltage due to static electricity is applied to the pin structure of optical modulation section 4, a high electric field is formed in the pin structure of optical modulation section 4. Since the laser light is absorbed by second active layer 42 during optical modulation, carriers (electrons and holes) are generated in optical modulation section 4. The carriers are accelerated by the high electric field, and impact atoms constituting the semiconductor layers forming the pin structure of optical modulation section 4. This impact generates new carriers. Such impact ionization occurs in a chained manner, and a large current due to avalanche breakdown flows through the pin structure of optical modulation section 4. Electrostatic destruction (ESD) occurs in optical modulation section 4. Upper cladding layer 43 is a p-type semiconductor layer, and holes in upper cladding layer 43 have a large impact ion coefficient. Therefore, a large current is likely to be generated in upper cladding layer 43.

In the present embodiment, semiconductor region 44 and semiconductor region 45 are each disposed on a part between second active layer 42 and upper cladding layer 43. The first impact ionization coefficient of semiconductor region 44 and the second impact ionization coefficient of semiconductor region 45 are each smaller than the impact ionization coefficient of upper cladding layer 43. Accordingly, in semiconductor region 44 and semiconductor region 45, occurrence of impact ionization in a chained manner during optical modulation is suppressed. Even when an instantaneous high voltage due to static electricity is applied to the pin structure of optical modulation section 4, it is possible to prevent a large current from flowing through the pin structure of optical modulation section 4. Optical semiconductor integrated device 1 has an improved resistance to electrostatic destruction (ESD).

Further, the resistance to electrostatic destruction (ESD) can be improved without increasing the thickness of the i layer (second active layer 42) of the pin structure of optical modulation section 4. Accordingly, the extinction ratio of optical modulation section 4 is not reduced.

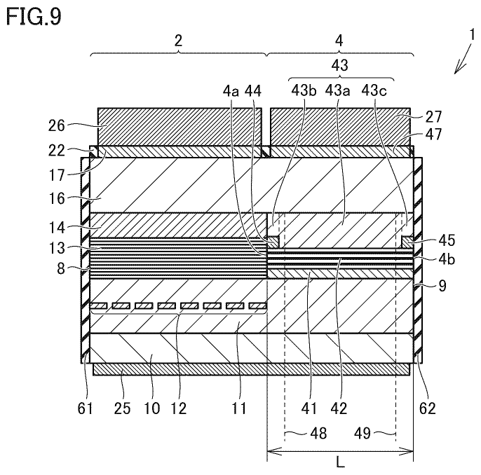

Referring to FIGS. 8 and 9, optical semiconductor integrated device 1 according to variations of the present embodiment will be described.

As in optical semiconductor integrated device 1 according to a first variation of the present embodiment shown in FIG. 8, passive waveguide section 3 may be omitted from optical semiconductor integrated device 1 according to the present embodiment (see FIGS. 1 and 2). In optical semiconductor integrated device 1, optical modulation section 4 is disposed between laser section 2 and spot size conversion section 5, and is connected to laser section 2 and spot size conversion section 5. End surface 4a faces laser section 2, and is an interface between laser section 2 and optical modulation section 4. Semiconductor region 44 is in contact with second active layer 42, upper cladding layer 43, and laser section 2 (specifically, first active layer 13).

As in optical semiconductor integrated device 1 according to a second variation of the present embodiment shown in FIG. 9, passive waveguide section 3 and spot size conversion section 5 may be omitted from optical semiconductor integrated device 1 according to the present embodiment (see FIGS. 1 and 2). In optical semiconductor integrated device 1, optical modulation section 4 is connected to laser section 2. End surface 4a faces laser section 2, and is an interface between laser section 2 and optical modulation section 4. End surface 4b is end surface 9 of optical semiconductor integrated device 1. Semiconductor region 44 is in contact with second active layer 42, upper cladding layer 43, and laser section 2 (specifically, first active layer 13). Semiconductor region 45 is in contact with second active layer 42 and upper cladding layer 43. Semiconductor region 45 is disposed on end surface 9, and constitutes a part of end surface 4b.

In a third variation of the present embodiment, one of semiconductor region 44 and semiconductor region 45 may be omitted.

Effects of optical semiconductor integrated device 1 according to the present embodiment will be described.

Optical semiconductor integrated device 1 according to the present embodiment includes optical modulation section 4, and a semiconductor waveguide element section (for example, passive waveguide section 3) connected to optical modulation section 4. Optical modulation section 4 includes an active layer (second active layer 42), upper cladding layer 43, and a first semiconductor region (for example, semiconductor region 44) having the same conductivity type as that of upper cladding layer 43. The first semiconductor region is disposed on a part between the active layer and upper cladding layer 43. The first impact ionization coefficient of the first semiconductor region is smaller than the impact ionization coefficient of upper cladding layer 43.

Accordingly, in the first semiconductor region (for example, semiconductor region 44), occurrence of impact ionization in a chained manner during optical modulation is suppressed. Even when an instantaneous high voltage due to static electricity is applied to optical modulation section 4, it is possible to prevent a large current due to avalanche breakdown from flowing through optical modulation section 4, without increasing the thickness of the active layer (second active layer 42).

According to optical semiconductor integrated device 1, the resistance to electrostatic destruction (ESD) can be improved without reducing the extinction ratio of optical modulation section 4.

In optical semiconductor integrated device 1 according to the present embodiment, optical modulation section 4 includes a first end surface (for example, end surface 4a) facing the semiconductor waveguide element section (for example, passive waveguide section 3), and a second end surface (for example, end surface 4b) opposite to the first end surface. The first semiconductor region (for example, semiconductor region 44) is disposed on the first end surface.

A large current that causes electrostatic destruction (ESD) is likely to flow through the end surfaces of optical modulation section 4. The first semiconductor region (for example, semiconductor region 44) is disposed on the first end surface (for example, end surface 4a). Accordingly, the large current that causes ESD can be effectively suppressed. According to optical semiconductor integrated device 1, the resistance to ESD can be improved without reducing the extinction ratio of optical modulation section 4.

In optical semiconductor integrated device 1 according to the present embodiment, the first semiconductor region (for example, semiconductor region 44) is disposed between the first end surface (for example, end surface 4a) and first imaginary surface 48 that is away from the first end surface by one tenth of modulation section length L. Modulation section length L is a distance between the first end surface and the second end surface (for example, end surface 4b) in the active layer.

Accordingly, a decrease in the reverse bias voltage applied to second active layer 42 due to the first semiconductor region (for example, semiconductor region 44) can be suppressed. According to optical semiconductor integrated device 1, the resistance to ESD can be improved without reducing the extinction ratio of optical modulation section 4.

In optical semiconductor integrated device 1 according to the present embodiment, upper cladding layer 43 is formed of p-type InP. The first semiconductor region (for example, semiconductor region 44) is formed of InGaAsP lattice-matched to upper cladding layer 43.

The absorption edge wavelength of second active layer 42 can be prevented from changing due to lattice mismatch between the first semiconductor region (for example, semiconductor region 44) and upper cladding layer 43. According to optical semiconductor integrated device 1, the resistance to ESD can be improved without reducing the extinction ratio of optical modulation section 4.

In optical semiconductor integrated device 1 according to the present embodiment, optical modulation section 4 includes a second semiconductor region (for example, semiconductor region 45) having the same conductivity type as that of upper cladding layer 43. The second semiconductor region is disposed on a part between the active layer (second active layer 42) and upper cladding layer 43, and is away from the first semiconductor region (for example, semiconductor region 44). The second impact ionization coefficient of the second semiconductor region is smaller than the impact ionization coefficient of upper cladding layer 43.

Accordingly, in the second semiconductor region (for example, semiconductor region 45), occurrence of impact ionization in a chained manner during optical modulation is suppressed. Even when an instantaneous high voltage due to static electricity is applied to optical modulation section 4, it is possible to prevent a large current due to avalanche breakdown from flowing through optical modulation section 4, without increasing the thickness of the active layer (second active layer 42). According to optical semiconductor integrated device 1, the resistance to electrostatic destruction (ESD) can be improved without reducing the extinction ratio of optical modulation section 4.

In optical semiconductor integrated device 1 according to the present embodiment, the second semiconductor region (for example, semiconductor region 45) is disposed on the second end surface (for example, end surface 4b).

A large current that causes electrostatic destruction (ESD) is likely to flow through the end surfaces of optical modulation section 4. The second semiconductor region (for example, semiconductor region 45) is disposed on the second end surface (for example, end surface 4b). Accordingly, the large current that causes ESD can be effectively suppressed. According to optical semiconductor integrated device 1, the resistance to ESD can be improved without reducing the extinction ratio of optical modulation section 4.

In optical semiconductor integrated device 1 according to the present embodiment, the first semiconductor region (for example, semiconductor region 44) is disposed between the first end surface (for example, end surface 4a) and first imaginary surface 48 that is away from the first end surface by one tenth of modulation section length L. The second semiconductor region (for example, semiconductor region 45) is disposed between the second end surface (for example, end surface 4b) and second imaginary surface 49 that is away from the second end surface by one tenth of modulation section length L. Modulation section length L is a distance between the first end surface and the second end surface in the active layer.

Accordingly, a decrease in the reverse bias voltage applied to second active layer 42 due to the first semiconductor region (for example, semiconductor region 44) and the second semiconductor region (for example, semiconductor region 45) can be suppressed. According to optical semiconductor integrated device 1, the resistance to ESD can be improved without reducing the extinction ratio of optical modulation section 4.

In optical semiconductor integrated device 1 according to the present embodiment, upper cladding layer 43 is formed of p-type InP. The first semiconductor region (for example, semiconductor region 44) and the second semiconductor region (for example, semiconductor region 45) are each formed of InGaAsP lattice-matched to upper cladding layer 43.

The absorption edge wavelength of second active layer 42 can be prevented from changing due to lattice mismatch between the first semiconductor region (for example, semiconductor region 44) and upper cladding layer 43 and lattice mismatch between the second semiconductor region (for example, semiconductor region 45) and upper cladding layer 43. According to optical semiconductor integrated device 1, the resistance to ESD can be improved without reducing the extinction ratio of optical modulation section 4.

Optical semiconductor integrated device 1 according to the present embodiment further includes laser section 2. The semiconductor waveguide element section is passive waveguide section 3 connected to laser section 2 and optical modulation section 4.

According to optical semiconductor integrated device 1, the resistance to ESD can be improved without reducing the extinction ratio of optical modulation section 4.

In optical semiconductor integrated device 1 according to the present embodiment, the semiconductor waveguide element section is laser section 2.

According to optical semiconductor integrated device 1, the resistance to ESD can be improved without reducing the extinction ratio of optical modulation section 4.

Optical semiconductor integrated device 1 according to the present embodiment further includes spot size conversion section 5. The second end surface (for example, end surface 4b) faces spot size conversion section 5.

According to optical semiconductor integrated device 1, the resistance to ESD can be improved without reducing the extinction ratio of optical modulation section 4.

In optical semiconductor integrated device 1 according to the present embodiment, the second end surface (for example, end surface 4b) is the output end surface (end surface 9) of optical semiconductor integrated device 1.

According to optical semiconductor integrated device 1, the resistance to ESD can be improved without reducing the extinction ratio of optical modulation section 4.

It should be understood that the embodiment disclosed herein is illustrative and non-restrictive in every respect. The scope of the present disclosure is defined by the scope of the claims, rather than the description above, and is intended to include any modifications within the scope and meaning equivalent to the scope of the claims.

### REFERENCE SIGNS LIST

1: optical semiconductor integrated device; 2: laser section; 3: passive waveguide section;, 4: optical modulation section; 4a, 4b: end surface; 5: spot size conversion section; 8, 9: end surface; 10: semiconductor substrate; 11: lower cladding layer; 12: diffraction grating; 13: first active layer; 14: upper cladding layer; 15: current blocking layer; 15a: semi-insulating semiconductor layer; 15b: n-type semiconductor layer; 16: upper cladding layer; 17: contact layer; 20, 21: groove; 22: insulating protective film; 25: first electrode; 26: second electrode; 27: third electrode; 28: pad; 29: bridge wire; 30: passive waveguide; 41: lower cladding layer; 42: second active layer; 43: upper cladding layer; 43a: first portion; 43b: second portion; 43c: third portion; 44: first semiconductor region; 45: second semiconductor region; 47: contact layer; 48: first imaginary surface; 49: second imaginary surface; 51: spot size conversion waveguide; 52: window region; 61: high reflection film; 62: antireflection film.

1. An optical semiconductor integrated device comprising:
an optical modulation section; and
a semiconductor waveguide element section connected to the optical modulation section, wherein
the optical modulation section includes an active layer, an upper cladding layer, and a first semiconductor region having a same conductivity type as that of the upper cladding layer,
the first semiconductor region is disposed on a part between the active layer and the upper cladding layer in a stacking direction and is disposed such that the first semiconductor region overlaps only a part of the active layer in an in-plane direction, and
a first impact ionization coefficient of the first semiconductor region is smaller than an impact ionization coefficient of the upper cladding layer.

2. The optical semiconductor integrated device according to claim 1, wherein
the optical modulation section includes a first end surface facing the semiconductor waveguide element section, and a second end surface opposite to the first end surface, and
the first semiconductor region is disposed on the first end surface.

3. The optical semiconductor integrated device according to claim 2, wherein
the first semiconductor region is disposed between the first end surface and a first imaginary surface that is away from the first end surface by one tenth of a modulation section length, and
the modulation section length is a distance between the first end surface and the second end surface in the active layer.

4. The optical semiconductor integrated device according to claim 1, wherein
the upper cladding layer is formed of p-type InP, and
the first semiconductor region is formed of InGaAsP lattice-matched to the upper cladding layer.

5. The optical semiconductor integrated device according to claim 2, wherein
the optical modulation section includes a second semiconductor region having a same conductivity type as that of the upper cladding layer,
the second semiconductor region is disposed on a part between the active layer and the upper cladding layer, and is away from the first semiconductor region, and
a second impact ionization coefficient of the second semiconductor region is smaller than the impact ionization coefficient of the upper cladding layer.

6. The optical semiconductor integrated device according to claim 5, wherein the second semiconductor region is disposed on the second end surface.

7. The optical semiconductor integrated device according to claim 6, wherein
the first semiconductor region is disposed between the first end surface and a first imaginary surface that is away from the first end surface by one tenth of a modulation section length,
the second semiconductor region is disposed between the second end surface and a second imaginary surface that is away from the second end surface by one tenth of the modulation section length, and
the modulation section length is a distance between the first end surface and the second end surface in the active layer.

8. The optical semiconductor integrated device according to claim 5, wherein the upper cladding layer is formed of p-type InP, and
the first semiconductor region and the second semiconductor region are each formed of InGaAsP lattice-matched to the upper cladding layer.

9. The optical semiconductor integrated device according to claim 1, further comprising a laser section, wherein
the semiconductor waveguide element section is a passive waveguide section connected to the laser section and the optical modulation section.

10. The optical semiconductor integrated device according to claim 1, wherein the semiconductor waveguide element section is a laser section.

11. The optical semiconductor integrated device according to claim 5, further comprising a spot size conversion section, wherein
the second end surface faces the spot size conversion section.

12. The optical semiconductor integrated device according to claim 5, wherein the second end surface is an output end surface of the optical semiconductor integrated device.
